(19) United States
(12) Patent Application Publication
(10) Pub. No.: US 2013/0183612 A1
(43) Pub. Date: Jul. 18, 2013

(54) METHOD FOR PRODUCING SUBSTRATE FOR LIQUID CRYSTAL DISPLAY PANEL, AND PHOTOMASK

(71) Applicants: Yutaka Sawayama, Osaka-shi (JP); Yasuo Fujii, Osaka-shi (JP)

(72) Inventors: Yutaka Sawayama, Osaka-shi (JP); Yasuo Fujii, Osaka-shi (JP)

(73) Assignee: SHARP KABUSHIKI KAISHA, Osaka-shi, Osaka (JP)

(21) Appl. No.: 13/876,499

(22) PCT Filed: Sep. 27, 2011
(86) PCT No.: PCT/JP2011/071964

§ 371 Date: Mar. 28, 2013

(30) Foreign Application Priority Data
Oct. 5, 2010 (JP) 2010-225964

(51) Int. Cl. G03F 1/60; G03F 1/00

(52) U.S. Cl. CPC G03F 1/60; G03F 1/00
USPC 430/5; 430/322

(57) ABSTRACT

The present invention provides a method for producing a substrate for a liquid crystal display panel and a photomask each of which can suppress misalignment of liquid crystal molecules due to liquid crystal alignment control projections. The present invention relates to a method for producing a substrate for a liquid crystal display panel. The substrate includes liquid crystal alignment control projections, and the liquid crystal alignment control projections include a main projection and a sub-projection. The sub-projection is linear and is lower than the main projection. The production method includes a step of forming a positive photosensitive resin film and a step of exposing the photosensitive resin film to light through a photomask. The photomask has a light-control region for forming the sub-projection. The light-control region has a slit-shaped translucent part.

### TECHNICAL FIELD

The present invention relates to a method for producing a substrate for a liquid crystal display panel, and a photomask. The present invention specifically relates to a method for producing a substrate for a liquid crystal display panel that is suitably used for an MVA display mode, and a photomask used in the production method.

### BACKGROUND ART

Liquid crystal display (LCD) panels comprise a pair of substrates and a liquid crystal layer that is sandwiched therebetween. The liquid crystal layer receives a voltage applied from electrodes on the substrates, and the voltage changes the alignment of the liquid crystal molecules. This change leads to a change in the state of polarization of light passing the liquid crystal layer, and thereby an image appears.

Examples of the display modes for LCD panels include the following modes. One is a twisted nematic (TN) mode in which upper and lower substrates have electrodes formed thereon, the two substrates sandwich liquid crystal having positive dielectric anisotropy in a state that the liquid crystal is twisted by 90°, and the liquid crystal is switched by a vertical electric field that is perpendicular to the substrates. Another is a vertical alignment (VA) mode in which upper and lower substrates have liquid crystal having negative dielectric anisotropy sandwiched therebetween, and the liquid crystal molecules are vertically aligned by a vertical alignment film when no electric field is applied, while the liquid crystal molecules are horizontally aligned when an electric field is applied (for example, see Patent Literature 1).

Further, the VA mode develops into its applied technique, that is, a multi-domain vertical alignment (MVA) mode. Pixels of an MVA-mode LCD panel each are divided into multiple regions, in other words, formed into multi-domains by liquid crystal alignment control projections and/or electrode slits. For the MVA mode, the liquid crystal molecules in each pixel are controlled to tilt in multiple angles, leading to uniform gray-scale display in all directions. Thereby, the MVA mode provides excellent contrast, viewing angle characteristics, and response time.

The aforementioned liquid crystal alignment control projections can be formed by, for example, photolithography. Specifically, for example, a photosensitive resin composition that absorbs light within a photosensitive wavelength range is applied onto a color filter and the photosensitive resin composition is exposed to light through a photomask. Next, the exposed photosensitive resin composition is developed, forming a desired pattern (for example, see Patent Literatures 2 and 3).

### CITATION LIST

### Patent Literature

Patent Literature 1: JP 2002-148624 A

Patent Literature 2: JP 2004-61539 A

Patent Literature 3: JP 2006-201234 A

### SUMMARY OF INVENTION

### Technical Problem

Regions in each of which the liquid crystal molecules are aligned to a different direction from other regions are called domains. If two domains are adjacent to each other with the boundary therebetween has neither liquid crystal alignment control projections nor electrode slits, the following disadvantages (1) and (2) occur: (1) a faded-white region or dark line appears between the two domains; and (2) the position of the boundary between the two domains is unstable and the ratio in area of the two domains is not fixed.

In order to solve such disadvantages, the present inventors have performed studies on a structure of an MVA-mode liquid crystal display panel with higher liquid crystal alignment control projections (hereinafter, also referred to as main projections) disposed at a portion corresponding to an opening region and with lower liquid crystal alignment control projections (hereinafter, also referred to as sub-projections) supplementarily disposed in each pixel. Disposing not only a single type of liquid crystal alignment control projection so as to divide each pixel but also a subsidiary lower liquid crystal alignment control projection enables to divide the liquid crystal molecules more precisely into each region of the pixel. This increases the controllability of alignment of liquid crystal molecules and greatly improves the display quality. The sub-projection lies at a portion not corresponding to an opening region (e.g. a light-shielding region), for example.

An important matter is that the sub-projections each have a more gently tilted and more gently sloping surface than the main projections.

In order to simplify the production process, the main projections and the sub-projections are preferably formed simultaneously.

The present inventors have studied production methods using the following photomask. This photomask has a pattern corresponding to the main projections and a pattern corresponding to the sub-projections, and the latter pattern is narrower than the former pattern. This production method can provide lower and gentler sub-projections than main projections, in some cases.

However, the accuracy of a production device, especially the resolution of an exposure device, may make it difficult to adjust the shape of the sub-projection appropriately, in some cases. For example, an optical image-forming exposure device providing high resolution makes it difficult to form sub-projections with an appropriate shape. In this case, even a fine pattern corresponding to the sub-projections has difficulty in tapering the sub-projections.

FIG. 26 is a photomicrograph showing the surface of a substrate constituting an MVA-mode liquid crystal display panel that is in the state of an extinction position; the present inventors have studied on such an LCD panel. The substrate shown in FIG. 26 comprises liquid crystal alignment control projections formed using the aforementioned photomask with a fine pattern corresponding to sub-projections. Thereby, as shown in the circled portion in FIG. 26, a disclination line appears at a portion where the orientation of the liquid crystal molecules due to the sub-projections encounters with the orientation of the liquid crystal molecules due to the main projections. This is presumably due to a failure in achieving a required height difference between the sub-projections and the main projections and of the resulting excessive alignment control force of the sub-projections relative to the alignment control force of the main projections.

Disclination lines are observed as dark lines in the normal display state. Further, the disclination lines are unevenly distributed. Thus, the disclination lines cause reduction in brightness and uneven display.

Because the picture of FIG. 26 shows the state of an extinction position, the disclination line is observed as a bright line in FIG. 26.

The present invention is devised in the above situation, and aims to provide a method for producing a substrate for a liquid crystal display panel that can suppress misalignment of the liquid crystal molecules due to liquid crystal alignment control projections, and a photomask.

### Solution to Problem

The present inventors have performed various studies on a method for producing a substrate for a liquid crystal display panel that can suppress misalignment of liquid crystal molecules due to liquid crystal alignment control projections, and have focused on the pattern of a photomask.

Then, they have found that a gray-tone region for forming a sub-projection in the photomask and a slit-shaped translucent part in the gray-tone region enable to form a sub-projection with an appropriate shape. Thereby, the present inventors have arrived at the solution of the problems and completed the present invention.

One aspect of the present invention relates to a method for producing a substrate for a liquid crystal display panel, the substrate comprising liquid crystal alignment control projections including a main projection and a sub-projection that is linear and is lower than the main projection. The method comprises: a step of forming a positive photosensitive resin film; and a step of exposing the photosensitive resin film to light through a photomask.

The photomask includes a light-control region for forming the sub-projection, and the light-control region including a slit-shaped translucent part.

The production method of the present invention is not especially limited by other steps as long as the aforementioned steps are essentially included. Preferable embodiments of the production method of the present invention are mentioned in more detail below.

In one preferable embodiment (hereinafter, also referred to as a first embodiment) of the production method of the present invention, the photomask further includes a translucent region and a light-shielding region for forming the main projection. The light-control region is a gray-tone region including a light-shielding part and the translucent part.

The first embodiment enables to form a sub-projection with an appropriate shape and a main projection simultaneously.

In one preferable sub-embodiment (hereinafter, also referred to as a second embodiment) of the first embodiment, the substrate further comprises a color layer and a light-shielding layer that is higher than the color layer. The sub-projection is a first sub-projection disposed on the color layer. The liquid crystal alignment control projections further include a second sub-projection disposed on the light-shielding layer. The second sub-projection is linear and is lower than the main projection. In addition, the gray-tone region is a first gray-tone region for forming the first sub-projection. The light-shielding part and the translucent part are a first light-shielding part and a first translucent part, respectively.

The photomask further includes a second gray-tone region for forming the second sub-projection. The second gray-tone region includes a second light-shielding part and a slit-shaped second translucent part, and the second gray-tone region has a higher transmissivity than the first gray-tone region.

The second embodiment enables to form the color layer in each division defined by the light-shielding layer with a step between the light-shielding layer and the color layer so that the light-shielding layer is higher than the color layer. Therefore, the color layer can be appropriately patterned. Further, the second embodiment enables to make the second sub-projection lower than the first sub-projection. In other words, this embodiment can provide a smaller difference between the height from the substrate surface to the first sub-projection and the height from the substrate surface to the second sub-projection. Therefore, it enables to further suppress misalignment of liquid crystal molecules.

In another preferable embodiment (hereinafter, also referred to as a third embodiment) of the production method of the present invention, the substrate further comprises a columnar spacer. The photomask further includes a translucent region, a light-shielding region for forming the columnar spacer, and a half-tone region for forming the main projection. The light-control region is a half-tone/gray-tone region including a partially translucent part and the translucent part.

The third embodiment enables to form a sub-projection with an appropriate shape, a main projection, and a columnar spacer simultaneously.

In one preferable sub-embodiment (hereinafter, also referred to as a fourth embodiment) of the third embodiment, the substrate further comprises a color layer and a light-shielding layer that is higher than the color layer. The sub-projection is a first sub-projection that is disposed on the color layer. The liquid crystal alignment control projections further include a second sub-projection disposed on the light-shielding layer, and the second sub-projection is linear and is lower than the main projection. The half-tone/gray-tone region is a first half-tone/gray-tone region for forming the first sub-projection. The partially translucent part and the translucent part are a first partially translucent part and a first translucent part, respectively. The photomask further includes a second half-tone/gray-tone region for forming the second sub-projection. The second half-tone/gray-tone region includes a second partially translucent part and a slit-shaped second translucent part, and the second half-tone/gray-tone region has a higher transmissivity than the first half-tone/gray-tone region.

The fourth embodiment enables to exert the same effects as the second embodiment.

In another preferable sub-embodiment (hereinafter, also referred to as a fifth embodiment) of the third embodiment, the translucent part is a first translucent part. The photomask further includes a gray-tone region. The gray-tone region includes a light-shielding part and a slit-shaped second translucent part.

The fifth embodiment enables to form four patterns having different heights.

Another aspect of the present invention relates to a photomask (hereinafter, also referred to as a photomask of the present invention) used in a process of producing a substrate for a liquid crystal display panel, the substrate comprises liquid crystal alignment control projections including a main projection and a sub-projection that is linear and is lower than the main projection. The photomask comprises a light-control region for forming the sub-projection. The light-control region includes a slit-shaped translucent part.

The configuration of the photomask of the present invention is not especially limited by other components as long as it essentially includes such components. The following will specifically describe preferable embodiments of the photomask of the present invention.

In one preferable embodiment (hereinafter, also referred to as a sixth embodiment) of the photomask of the present invention, the photomask further includes a translucent region and a light-shielding region for forming the main projection. The light-control region is a gray-tone region including a light-shielding part and the translucent part.

The sixth embodiment enables to exert the same effects as the first embodiment.

In one preferable sub-embodiment (hereinafter, also referred to as a seventh embodiment) of the sixth embodiment, the substrate further comprises a color layer and a light-shielding layer that is higher than the color layer. The sub-projection is a first sub-projection disposed on the color layer. The liquid crystal alignment control projections further include a second sub-projection disposed on the light-shielding layer. The second sub-projection is linear and is lower than the main projection. The gray-tone region is a first gray-tone region for forming the first sub-projection. The light-shielding part and the translucent part are a first light-shielding part and a first translucent part, respectively. The photomask further includes a second gray-tone region for forming the second sub-projection. The second gray-tone region includes a second light-shielding part and a slit-shaped second translucent part, and the second gray-tone region has a higher transmissivity than the first gray-tone region.

The seventh embodiment enables to exert the same effects as the second embodiment.

In another preferable embodiment (hereinafter, also referred to as an eighth embodiment) of the photomask of the present invention, the substrate further comprises a columnar spacer. The photomask further includes a translucent region, a light-shielding region for forming the columnar spacer, and a half-tone region for forming the main projection. The light-control region is a half-tone/gray-tone region including a partially translucent part and the translucent part.

The eighth embodiment enables to exert the same effects as the third embodiment.

In one preferable sub-embodiment (hereinafter, also referred to as a ninth embodiment) of the eighth embodiment, the substrate further comprises a color layer and a light-shielding layer that is higher than the color layer. The sub-projection is a first sub-projection that is formed on the color layer. The liquid crystal alignment control projections further include a second sub-projection formed on the light-shielding layer. The second sub-projection is linear and is lower than the main projection. The half-tone/gray-tone region is a first half-tone/gray-tone region for forming the first sub-projection. The partially translucent part and the translucent part are a first partially translucent part and a first translucent part, respectively. The photomask further includes a second half-tone/gray-tone region for forming the second sub-projection. The second half-tone/gray-tone region includes a second partially translucent part and a slit-shaped second translucent part, and the second half-tone/gray-tone region has a higher transmissivity than the first half-tone/gray-tone region.

The ninth embodiment enables to exert the same effects as the second embodiment.

In one preferable sub-embodiment (hereinafter, also referred to as a tenth embodiment) of the eighth embodiment, the translucent part is a first translucent part. The photomask further includes a gray-tone region. The gray-tone region includes a light-shielding part and a slit-shaped second translucent part.

The tenth embodiment enables to exert the same effects as the fifth embodiment. cl Advantageous Effects of Invention

The present invention enables to provide a method for producing a substrate for a liquid crystal display panel and a photomask each of which can suppress misalignment of liquid crystal molecules due to liquid crystal alignment control projections.

### BRIEF DESCRIPTION OF THE DRAWINGS

FIG. 1 is a schematic plan view showing an opposite substrate of Embodiment 1.

FIG. 2 is a schematic cross-sectional view along the A1-A2 line in FIG. 1.

FIG. 3 is a schematic perspective view showing liquid crystal alignment control projections on the opposite substrate of Embodiment 1.

FIG. 4 is a schematic cross-sectional view of a photomask of Embodiment 1 showing the production method of

Embodiment 1.

FIG. 5 is a schematic plan view of the photomask of Embodiment 1.

FIG. 6 is a schematic cross-sectional view along the B1-B2 line in FIG. 5.

FIG. 7 is an enlarged schematic plan view showing a GT region (gray-tone region) of the photomask of Embodiment 1.

FIG. 8 is an enlarged schematic plan view showing a GT region of a photomask of one modified example of

Embodiment 1.

FIG. 9 is an enlarged schematic plan view showing a GT region of a photomask of another modified example of Embodiment 1.

FIG. 10 is a graph showing the relation between the transmissivity of a GT region and the height of a sub-rib.

FIG. 11 is an enlarged schematic plan view showing a light-shielding pattern of a photomask of Comparative Embodiment 1.

FIG. 12 is an enlarged schematic plan view showing a first GT region of the photomask of Embodiment 1.

FIG. 13 is an enlarged schematic plan view showing a second GT region of the photomask of Embodiment 1.

FIG. 14 is a schematic plan view showing part of the rib of Embodiment 1.

FIG. 15 shows cross-sectional profiles of sub-ribs formed by the production methods of Embodiment 1 and Comparative Embodiment 2.

FIG. 16 shows the tilt angle distribution of the surfaces of the sub-ribs formed by the production methods of Embodiment 1 and Comparative Embodiment 2.

FIG. 17 is a photomicrograph of the surface of a substrate constituting a liquid crystal display panel of Comparative Embodiment 3 in the normal display state.

FIG. 18 is a photomicrograph of the surface of a substrate constituting the liquid crystal display panel of Embodiment 1 in the normal display state.

FIG. 19 is another photomicrograph of the surface of the substrate constituting the liquid crystal display panel of Embodiment 1 in the state of an extinction position.

FIG. 20 is a schematic plan view showing an opposite substrate of Embodiment 2.

FIG. 21 is a schematic cross-sectional view along the C1-C2 line in FIG. 20.

FIG. 22 is a schematic plan view showing a photomask of Embodiment 2.

FIG. 23 is a schematic cross-sectional view along the D1-D2 line in FIG. 22.

FIG. 24 shows cross-sectional profiles of the main ribs in Embodiment 1 and Embodiment 2.

FIG. 25 is a schematic cross-sectional view showing a photomask of Embodiment 3.

FIG. 26 is a photomicrograph showing the surface of a substrate constituting an MVA-mode liquid crystal display panel which is in the state of an extinction position and on which the present inventors have studied.

FIG. 27 is an enlarged schematic plan view showing a first HT/GT region of the photomask of Embodiment 2.

FIG. 28 is an enlarged schematic plan view showing a second HT/GT region of the photomask of Embodiment 2.

### DESCRIPTION OF EMBODIMENTS

The present invention will be mentioned in more detail referring to the drawings in the following embodiments, but is not limited to these embodiments.

The following description of the embodiments also refers to comparative embodiments.

### Embodiment 1

A liquid crystal display panel of Embodiment 1 comprises a pair of substrates and a liquid crystal layer disposed between the substrates. The liquid crystal display panel of Embodiment 1 is of an MVA mode. Each of the substrates has a vertical alignment film on the surface facing the liquid crystal layer. The liquid crystal layer contains nematic liquid crystal with negative dielectric anisotropy.

One substrate (hereinafter, also referred to as an array substrate) of the liquid crystal display panel of Embodiment 1 has gate bus lines extending in the row direction and source bus lines extending in the column direction. These lines define regions each serving as one sub-pixel.

The array substrate has multiple pixel electrodes, and the pixel electrodes are disposed for the sub-pixels in a one-to-one relation. In other words, the pixel electrodes are arranged in the row direction and the column direction to form a matrix pattern. The pixel electrodes are separately controlled by lines such as the gate bus lines and the source bus lines disposed in the gaps between the pixel electrodes, and by switching elements such as thin film transistors (TFTs) disposed adjacent to the respective intersection points of the gate bus lines and the source bus lines.

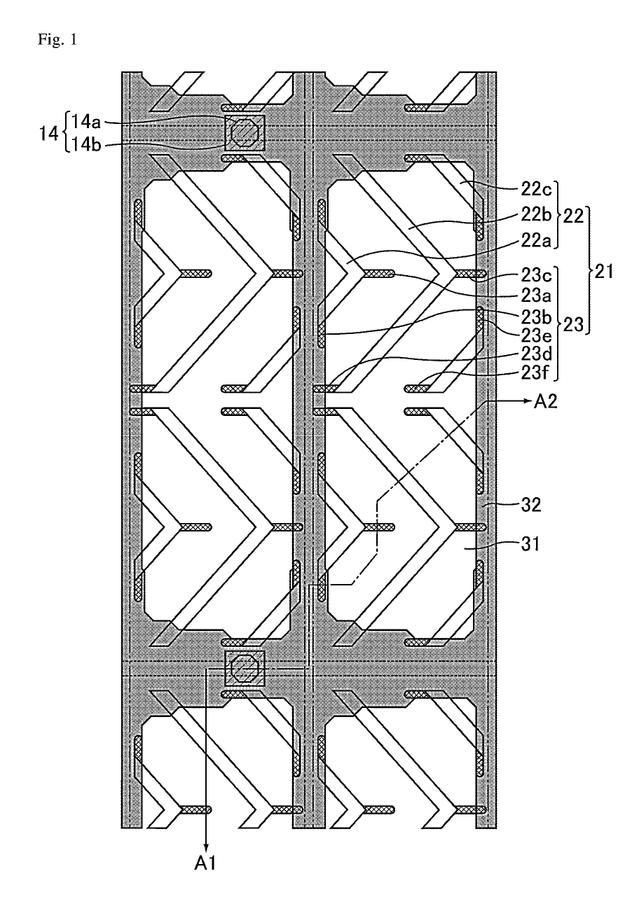

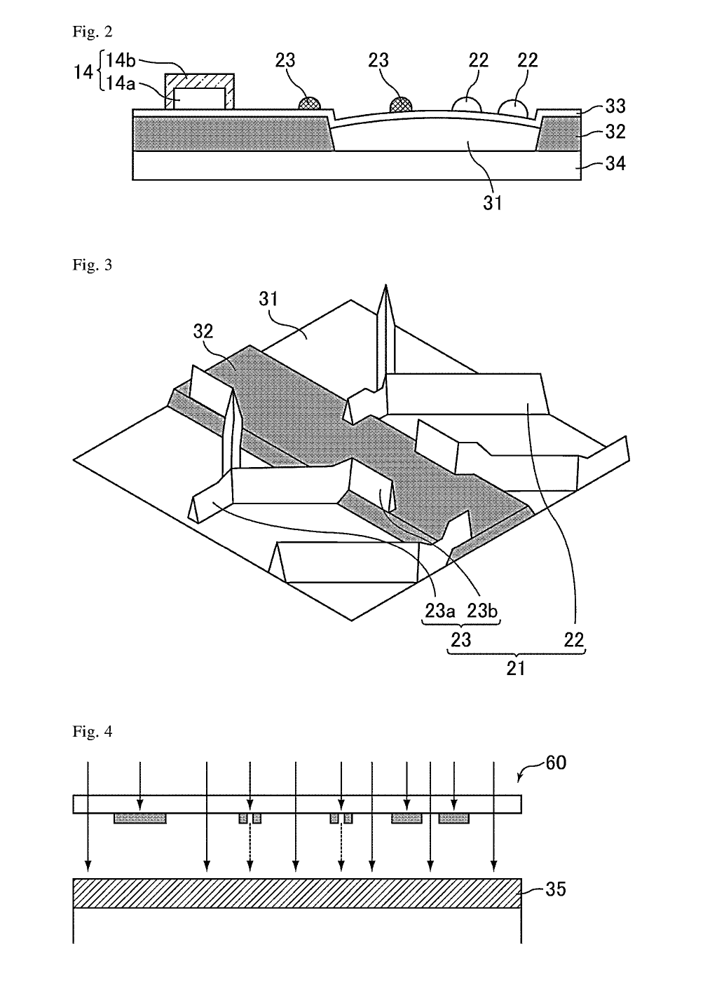

FIG. 1 is a schematic plan view showing the other substrate of the liquid crystal display panel of Embodiment 1. FIG. 2 is a schematic cross-sectional view along an A1-A2 line in FIG. 1. FIG. 1 and FIG. 2 show that the other substrate (hereinafter, also referred to as an opposite substrate) comprises color filters 31 disposed at the respective regions corresponding to the sub-pixels in one-to-one relation. The color filters 31 overlap the pixel electrodes. The color filters 31 may be disposed not on the opposite substrate but on the array substrate.

The multiple color filters 31 with multiple colors give a specific color of each pixel. Each pixel is constituted by multiple sub-pixels corresponding to the color filters 31. The combination of the colors of the color filters 31 constituting one pixel may, for example, be combination of the three primary colors, that is, red (R), green (G), and blue (B). Any of other colors (e.g. yellow (Y), white (W)) may be further included.

At any places between the pixel electrodes are disposed columnar spacers 14 that keep the gap constant between the substrates constituting the liquid crystal display panel. The spacer 14 has a pedestal part (lower portion) 14a and a height-adjusting part (upper portion) 14b formed on the pedestal part 14a.

The opposite substrate comprises a light-shielding member (hereinafter, also referred to as a black matrix (BM)) 32 disposed between the color filters 31, and this member suppresses light leakage between the color filters 31 and color mixture.

The color filters 31 and BM 32 are entirely covered with a common electrode 33. The common electrode 33 and the pixel electrodes on the array substrate form an electric field in the liquid crystal layer.

The gate bus lines face the regions defined by a dotted line in FIG. 1, and the source bus lines face the regions defined by a two-dot chain line in FIG. 1.

The liquid crystal display panel of Embodiment 1 comprises liquid crystal alignment control projections (hereinafter, also referred to as ribs) 21 that are linear in a plan view of the panel surface (substrate surface). The ribs 21 are disposed on the common electrode 33 of the opposite substrate. The ribs 21 each are partially folded, and they form a zigzag shape when the display is observed as a whole without consideration of the division of the pixels. The extending direction of each rib 21 forms an angle (e.g. 30° to 60° ) with the short and long sides of the pixel electrode, in other words, with the row direction and the column direction. Thus, even one rib 21 can divide one sub-pixel into multiple regions.

The material of the ribs 21 is a dielectric (insulator) such as novolac resin, and it allows adjacent liquid crystal molecules to align (tilt) toward the ribs 21 even when no voltage is applied. The liquid crystal molecules in the respective regions divided by the ribs 21 are thus aligned in different directions, thereby achieving a wide viewing angle.

As shown in FIG. 1, the ribs 21 include main ribs (main projections) 22 and sub-ribs (sub-projections) 23. The main ribs 22 include V-shaped main ribs 22a and 22b and linear main ribs 22c. The sub-ribs 23 are linear and the extending directions thereof form angles with the extending directions of the main ribs 22. The V-shaped main ribs 22a and 22b make it easy to uniformly divide one sub-pixel and to achieve a wide viewing angle. Further, the subsidiary disposed sub-ribs 23 enable to control the orientation of the liquid crystal molecules more precisely, thereby improving the display quality.

The sub-ribs 23 include sub-ribs 23 a extending from the folded portions (bending parts) of the main ribs 22a, sub-ribs 23b extending from the ends of the main ribs 22a, sub-ribs 23c extending from the folded portions (bending parts) of the main ribs 22b, sub-ribs 23d extending from the ends of the main ribs 22b, and sub-ribs 23e and 23f extending from the ends of the main ribs 22c.

These sub-ribs 23 do not require an alignment control force as high as the main ribs 22. Thus, they are formed lower than the main ribs 22, and the widths thereof are equal to or narrower than the main ribs 22.

Specifically, the main ribs 22 are 1.0 to 2.0 μm (preferably 1.0 to 1.5 μm) in height, whereas the sub-ribs 23 are preferably lower than the main ribs and are 0.5 to 0.9 μm in height.

The sub-ribs 23 are preferably narrower than the main ribs 22. The sub-ribs 23 narrower than the main ribs 22 provide an increased aperture ratio. Although the narrow sub-ribs 23 cause a slight decrease in alignment control force, they are just subsidiary projections and hardly affect the display quality.

Specifically, the main ribs 22 are 10 to 15 μm (preferably 10.5 to 12 μm) in width, whereas the sub-ribs 23 are preferably narrower than the main ribs and are 3 to 8 μm in width.

The main ribs 22 extend in directions forming angles with the outer edges of the sub-pixel. The sub-ribs 23 extend in the row direction or the column direction.

The main ribs 22a to 22c and the sub-ribs 23a and 23f are disposed on the color filter 31 (inside the opening regions). The sub-ribs 23b and 23e are disposed on the BM 32 (outside the opening regions). The sub-ribs 23c and 23d are disposed on the color filter 31 and the BM 32.

FIG. 3 is a schematic perspective view showing the liquid crystal alignment control projections of the opposite substrate of Embodiment 1. As shown in FIG. 3, the ribs 21 constitute wall-like partition members which stick out toward the substrate opposite to the opposite substrate, in other words, the array substrate. Further, the ribs 21 divide the liquid crystal molecules near the surface of the opposite substrate into multiple partitioned regions.

Between the color filter (color layer) 31 and the BM (light-shielding layer) 32 is formed a step, and the BM 32 is formed higher than the color filter 31. Thus, a step is formed in one rib, that is, between the portion on the color filter 31 (e.g. sub-rib 23a) and the portion in the BM 32 (e.g. sub-rib 23b). This is a step formed in the process of producing the color filter 31 and the BM 32.

The following will describe the method for producing an opposite substrate of Embodiment 1.

First, a lattice-shaped BM 32 is formed on a transparent substrate 34 by photolithography. The material of the substrate 34 may be glass, for example.

Next, a color filter 31 is formed by ink-jet printing. Specifically, a color filter material is dripped into spaces defined by the BM 32 by ink-jet printing, and then the solvent is removed. Such a procedure enables to easily form the color filter 31 with a high accuracy.

In order to more precisely keep the color filter material in the target spaces, the surface where the color filter is to be formed thereon (the surface of the substrate 34) is subjected to lyophilic treatment, and the surface of the BM 32 is subjected to liquid-repelling treatment. In such a case, the color filter 31 and the BM 32 to be formed have different heights.

Such a step between the BM 32 and the color filter 31 causes a step between the ribs formed on the respective faces. The difference in height between the color filter 31 and the BM 32 formed by a common production process is 0.4 to 0.6 μm, and this is substantially equal to a normal height of a sub-rib (15% to 90% of the height of a main rib).

The color filter 31 may be formed by photolithography.

Next, a common electrode 33 is formed on the BM 32 and the color filter 31 by sputtering. The material of the common electrode 33 may be, for example, a transparent electric conductor such as ITO.

Before the formation of the common electrode 33, an overcoat layer (flattening layer) may be formed so as to cover the BM 32 and the color filter 31.

Next, ribs 21 and a pedestal part 14a of a spacer 14 are patterned simultaneously by photolithography.

Specifically, a positive photosensitive resin material (e.g. novolac resin) is first applied onto the substrate 34 using a slit coater or a spin coater, and then the solvent is removed. This provides a photosensitive resin film (photoresist film) 35 as shown in FIG. 4.

Next, as shown in FIG. 4, a photomask 60 was placed at a predetermined position, and the photosensitive resin film 35 was exposed to light through the photomask 60. The exposure is performed at 250 mJ/cm², for example. The specification of the photomask 60 will be described later.

The exposure device used in the present embodiment is not particularly limited, and examples thereof include steppers, mirror projection exposure devices, and proximity exposure devices.

Thereafter, the exposed photosensitive resin film 35 was developed for one minute using potassium hydroxide, and then baked at 200° C. for 20 minutes. This provides the ribs 21 and the pedestal part 14a of the spacer 14.

Next, a height-adjusting part 14b of the spacer 14 is formed by photolithography. The height of the height-adjusting part 14b depends on a desired cell gap.

Finally, a vertical alignment film is formed, thereby completing the opposite substrate of Embodiment 1.

The liquid crystal display panel of the present embodiment may be produced by a conventionally known method.

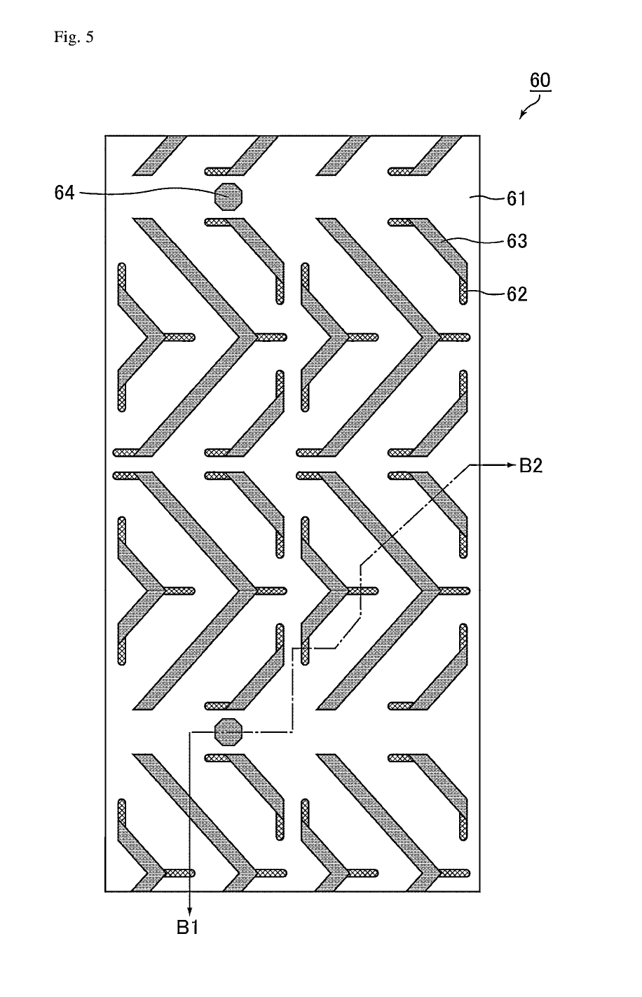

The photomask 60 is described below. FIG. 5 is a schematic plan view showing the photomask 60. As shown in FIG. 5, the photomask 60 of Embodiment 1 has a translucent region 61, gray-tone regions (GT regions) 62 which are light-control regions, and light-shielding regions 63 and 64. Each of the light-shielding regions 63 is V-shaped or linear, and each of the GT regions 62 is linear. The light-shielding regions 63 connect with the GT regions 62, and each of the light-shielding regions 63 extends in a direction forming an angle with the extending direction of each GT region 62. In other words, the shapes formed by combination of the GT region(s) 62 and the light-shielding region(s) 63 include a V-shape with a bending part.

The light-shielding regions 63 correspond to the portions of the resin film 35 that are to be formed into the main ribs 22. The GT regions 62 correspond to the portions of the resin film 35 that are to be formed into the sub-ribs 23. The light-shielding regions 64 correspond to the portions of the resin film 35 that are to be formed into the pedestal parts 14a.

The plane pattern of the light-shielding regions 63 is similar to the plane pattern of the main ribs 22. The plane pattern of the GT regions 62 is similar to the plane pattern of the sub-ribs 23. The plane pattern of the light-shielding regions 64 is similar to the plane pattern of the pedestal parts 14a.

As mentioned here, the light-shielding regions 63 are regions (pattern) for forming the main ribs 22, the GT regions 62 are regions (pattern) for forming the sub-ribs 23, and the light-shielding regions 64 are regions (pattern) for forming the pedestal parts 14a.

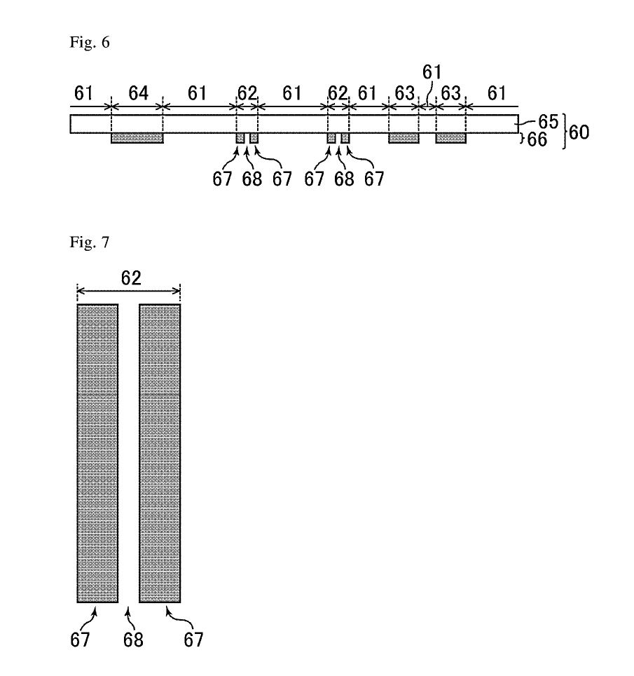

FIG. 6 is a schematic cross-sectional view along a B1-B2 line in FIG. 5.

As shown in FIG. 6, the photomask 60 has a transparent substrate (support) 65 and a light-shielding layer 66 patterned on the substrate 65.

The substrate 65 substantially perfectly transmits light applied. Specifically, the transmissivity at a wavelength of 360 to 440 nm of the substrate 65 is, for example, 80% or higher, and preferably 90 to 92%. The material of the substrate 65 may be, for example, glass such as soda lime glass or synthesized quartz glass.

The light-shielding layer 66 is formed by patterning a light-shielding thin film. The light-shielding layer 66 substantially perfectly shields light applied. Specifically, the transmissivity at a wavelength of 360 to 440 nm of the light-shielding layer 66 is substantially 0%. Therefore, no reaction occurs at the portions of the photosensitive resin film 35 that correspond to the light-shielding layers 66. The material of the light-shielding layer 66 may be, for example, a metal such as chromium.

The light-shielding layers 66 are formed at the entire light-shielding regions 63 and 64 and part of each of the GT regions 62, but are not formed at the translucent region 61. That is, the translucent region 61 only includes the substrate 65, and thus the translucent region 61 substantially perfectly transmits light applied. The light-shielding regions 63 and 64 substantially perfectly shield light applied.

The GT region 62 has light-shielding parts 67 and a translucent part 68 formed between the light-shielding parts 67. The translucent part 68 does not include the light-shielding layer 66 and include only the substrate 65. Thus, the translucent part 68 transmits substantially the whole light applied. In contrast, the light-shielding part 67 includes the light-shielding layer 66, and it substantially perfectly shields light applied. In other words, the GT region 62 transmits part of light applied.

The transmissivity at a wavelength of 360 to 440 nm of the GT region 62 is, for example, 10% (preferably 15%) or higher and 40% (preferably 25%) or lower. The transmissivity of the translucent region 61 is the same as the transmissivity of the substrate 65, and the transmissivity of each of the light-shielding regions 63 and 64 is the same as the transmissivity of the light-shielding layer 66. Thus, in the photomask 60, the transmissivity increases in the order of the light-shielding region 63, the GT region 62, and the translucent region 61.

Such a photomask 60 allows the portion corresponding to the translucent region 61 of the resin film 35 to mostly disappear, and allows the portions corresponding to the GT regions 62 of the resin film 35 to partially disappear. Further, it allows he portions corresponding to the light-shielding regions 63 and 64 of the resin film 35 to mostly remain. Thus, the sub-ribs 23 are formed at the portions corresponding to the GT regions 62, the main ribs 22 are formed at the portions corresponding to the light-shielding regions 63, and the pedestal parts 14 a are formed at the portions corresponding to the light-shielding regions 64. Further, all of the ribs 21 including the main ribs 22 and the sub-ribs 23 are patterned simultaneously.

FIG. 7 is an enlarged schematic plan view showing the GT region 62 of the photomask 60. As shown in FIG. 7, in the GT region 62, the translucent part 68 is formed like a slit (linearly formed). The translucent part 68 and the light-shielding parts 67 form a stripe pattern. Hereinafter, the translucent part 68 is also referred to as a slit.

The slit 68 is disposed in substantially parallel with the portion where the sub-rib 23 is to be formed. As mentioned here, the extending direction of the slit 68 corresponds to the extending direction of the sub-rib 23.

The slit 68 has a substantially uniform width. The width of the slit 68 is adjusted to be smaller than the resolution limit of an exposure device. In other words, the slit 68 is smaller than the resolution of an exposure device. Specifically, for example, the width of the slit 68 is about 3 μm (preferably 0.5 to 1.5 μm). This is because as follows: the resolution limit of an optical image-forming exposure device (e.g. stepper, mirror projection exposure device) is 0.1 to several micrometers; the resolution limit of a proximity exposure device is several nanometers; and the resolution limit (manufacturer's specification) of an exposure device for large TVs is about 3 to 4 μm.

The photomask 60 differs from a common gray-tone mask for semiconductor elements in that it does not require removal of interference waves. Thus, the width of the slit 68 does not require to be adjusted to n times of the wavelength of light for exposure.

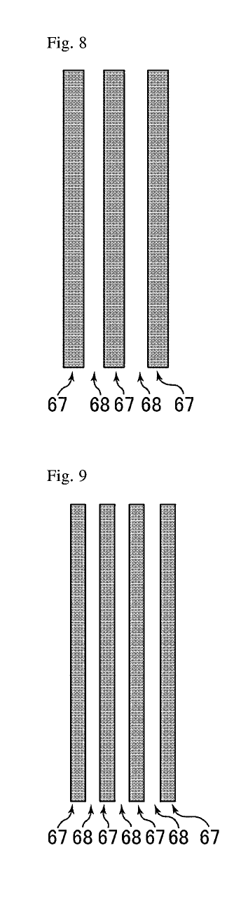

FIG. 8 and FIG. 9 each are an enlarged schematic plan view showing one modified example of the pattern of the GT region 62. FIG. 7 shows one slit 68, but the number of the slits 68 in one GT region 62 is not particularly limited. For example, the number of slits 68 may be two as shown in FIG. 8, or may be three as shown in FIG. 9, or may be four or more. The number of slits 68 is appropriately adjusted in consideration of the conditions such as widths and heights of the sub-ribs 23 and the resolution limit of an exposure device. For two or more slits 68, the slits 68 have substantially the same width.

For one slit 68, the center line of the slit 68 substantially corresponds to the center line of the GT region 62. For two slits 68, the slits 68 are disposed at the same intervals. In either case, the light-shielding parts 67 each have a substantially uniform width and the light-shielding parts 67 have substantially the same width.

Adjustment of the number and widths of the slits 68 leads to adjustment of the transmissivity of the GT region 62. This results in adjustment of the width and the height of each sub-rib 23.

FIG. 10 shows the result of plotting the relation between the transmissivities of the GT regions 62 and the heights of the sub-ribs 23, where the multiple sub-ribs 23 are formed using the GT regions 62 with the respective transmissivities and the heights of the sub-ribs are measured. FIG. 10 shows that the height of the sub-rib 23 decreases as the transmissivity of the GT region 62 decreases. In FIG. 10, the height of the sub-rib is defined as 100% in the case where the transmissivity of the GT region 62 of 0%, in other words, the GT region 62 is a light-shielding region.

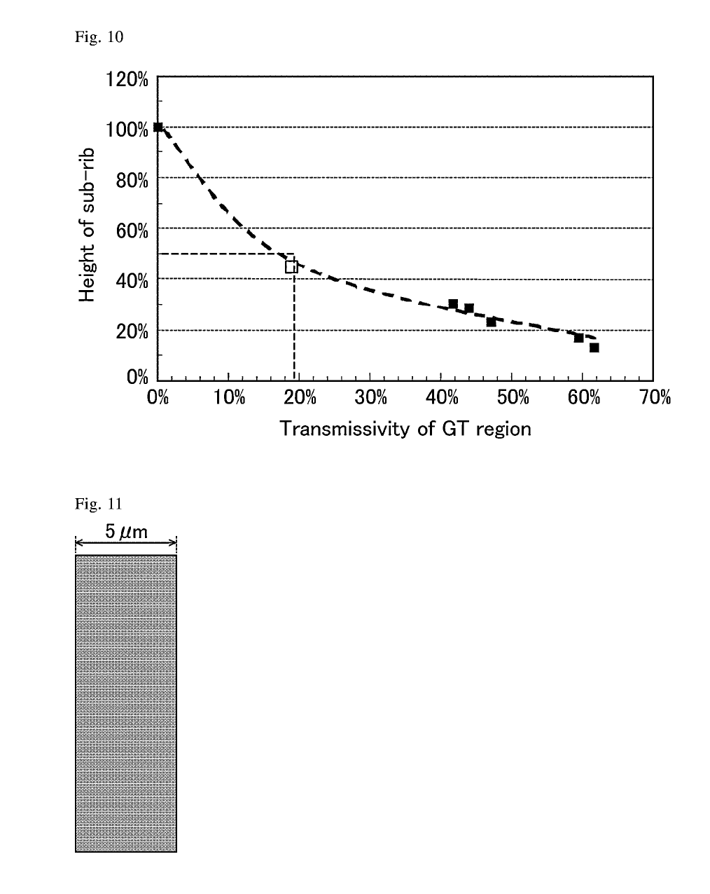

Table 1 shows the results of forming sub-ribs 23 using various GT regions 62 and measuring the widths and heights thereof. Table 1 further shows the results on sub-ribs formed by the production method in Comparative Embodiment 1. In Comparative Embodiment 1, sub-ribs are formed using a 5-μm-width light-shielding pattern without a slit, as shown in FIG. 11. In Table 1, the units for the widths and heights are μm.

TABLE 1

| | Comparative | | | | | | | | | | | |
|---|---|---|---|---|---|---|---|---|---|---|---|---|
| | Embodiment | | | | | | | | | | | |
| | 1 | | Embodiment 1 | | | | | | | | | |
| | Width | Number | Width | Number | Width | Number | Width | Number | Width | Number | Width | Number |
| Light- | 5.0 | 1 | 1.0 | 4 | 1.0 | 4 | 1.1 | 4 | 1.2 | 3 | 1.3 | 3 |
| shielding | | | | | | | | | | | | |
| part | | | | | | | | | | | | |
| Slit | | | 1.2 | 3 | 1.3 | 3 | 1.3 | 3 | 1.4 | 2 | 1.5 | 2 |

| | | | | | | |
|---|---|---|---|---|---|---|
| Width of | 4.04 | 7.6 | 7.9 | 8.3 | 6.4 | 6.9 |
| sub-rib | | | | | | |
| Height of | 1.19 | 0.59 | 0.46 | 0.61 | 0.64 | 0.72 |
| sub-rib | | | | | | |
| Transmis- | 0 | 47.4 | 49.4 | 47.0 | 43.8 | 43.5 |
| sivity (%) | | | | | | |
| Film | 0 | 50.4 | 61.3 | 48.7 | 46.2 | 39.5 |
| reduction | | | | | | |
| ratio (%) | | | | | | |

Table 1 shows that the sub-ribs 23 formed using the GT regions 62 are lower and thicker (gentler) than the sub-ribs in Comparative Embodiment 1. Such sub-ribs 23 can suppress misalignment of the liquid crystal molecules at around the folded portions and the end portions of the main ribs 22.

The “film reduction ratio” in Table 1 means a ratio (%) of the difference in height between the sub-rib 23 and the sub-rib in Comparative Embodiment 1 to the height of the sub-rib in Comparative Embodiment 1.

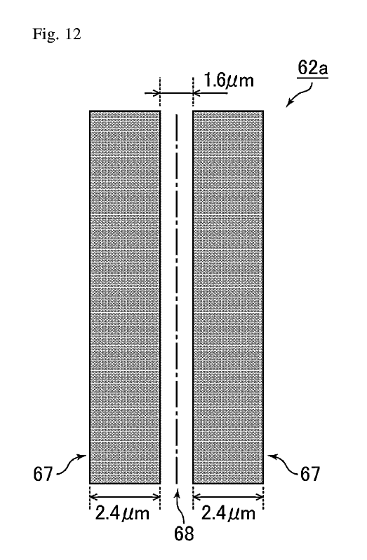

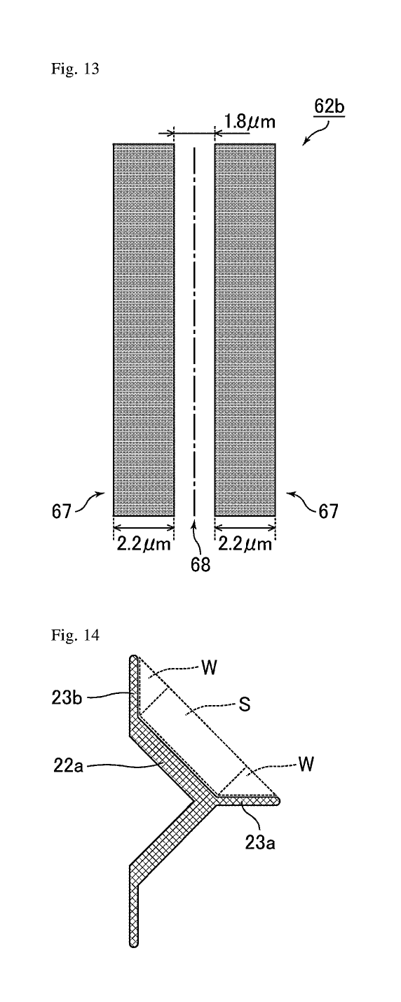

In the present embodiment, the GT regions 62 include first GT regions 62a with a lower transmissivity and second GT regions 62b with a higher transmissivity. FIG. 12 shows one example of the pattern of the GT region 62a, and FIG. 13 shows one example of the pattern of the GT region 62b. FIG. 12 and FIG. 13 show that the slit (first translucent part) 68 of the GT region 62a is narrower than the slit (second translucent part) 68 of the GT region 62b. Further, the light-shielding part (first light-shielding part) 67 of the GT region 62a is wider than the light-shielding part (second light-shielding part) 67 of the GT region 62b.

The GT regions 62a are used for forming the sub-ribs 23a, 23c, 23d, and 23f (first sub-projections) on the color filter 31, and the GT regions 62b are used for forming the sub-ribs 23b and 23e (second sub-projections) on the BM 32.

As mentioned here, the GT regions 62a are formed in accordance with the sub-ribs 23a, 23c, 23d, and 23f, and the GT regions 62b are formed in accordance with the sub-ribs 23b and 23e. As a result, the sub-ribs 23b and 23e are made lower while the sub-ribs 23a, 23c, 23d, and 23f are made higher.

As mentioned above, the color filter 31 and the BM 32 have different heights and the BM 32 is higher than the color filter 31. On the other hand, the sub-ribs 23b and 23e on the BM 32 are lower than the sub-ribs 23a, 23c, 23d, and 23f on the color filter 31. Thus, the difference between the height from the substrate 34 to the sub-ribs 23b and 23e and the height from the substrate 34 to the sub-ribs 23a, 23c, 23d, and 23f is small in contrast to the case where all the sub-ribs 23 have the same height. This leads to a liquid crystal display panel with less misalignment of the liquid crystal in comparison with the case where all the sub-ribs 23 have the same height.

With respect to the method for giving different transmissivities to the GT region 62a and the GT region 62b, a method of making the number of slits 68 different between the regions may be used instead of the method of making the width of the slit 68 different between the regions.

The following will specifically describe the shapes of the ribs formed by the production method of Embodiment 1.

The ribs 21 include higher and wider main ribs 22 and lower and narrower sub-ribs 23. FIG. 14 shows a schematic plan view showing one part of the ribs in Embodiment 1. Here, the main ribs 22a and the sub-ribs 23a and 23b are taken as examples. FIG. 14 shows that the main rib 22a is V-shaped and the sub-ribs 23a and 23b each are linear. The sub-rib 23a extends from the bending part of the main rib 22a and the sub-rib 23b extends from the tip of the main rib 22a. The liquid crystal molecules are aligned such that one end of each molecule is oriented to the rib 21. If no sub-rib 23b is formed at the tip of the main rib 22a, the liquid crystal molecules at a region around the tip of the main rib 22a may be misaligned. Similarly, the liquid crystal molecules at a region around the folded portion of the main rib 22a may be misaligned.

In Embodiment 1, the sub-ribs 23a and 23b serve as barriers that suppress misalignment of the liquid crystal molecules. Thus, the liquid crystal molecules are more securely divided and the sub-pixel is more regularly divided into domains.

In such a structure having the sub-ribs 23a and 23b, the regions (domains) formed by the ribs 21 include a main control domain S where the alignment is mainly controlled by the main rib 22a and sub control domains W where the alignment is mainly controlled by the sub-ribs 23a and 23b, as illustrated by dotted lines in FIG. 14.

Because the main rib 22a is higher than the sub-ribs 23a and 23b, the alignment control force of the main rib 22a is higher than that of each of the sub-ribs 23a and 23b. This enables to regularly control the alignment of the liquid crystal molecules in the main control domain S by a higher control force, whereas to control the alignment of the liquid crystal molecules in the sub control domain W by a lower control force.

Supposing that the relative alignment control forces of the sub-ribs 23a and 23b to the alignment control force of the main rib 22a become higher than necessary, the liquid crystal molecules in the sub control domains W are affected by the alignment control forces of the sub-ribs 23a and 23b more than necessary, and the liquid crystal molecules in the sub control domains W may be disadvantageously misaligned.

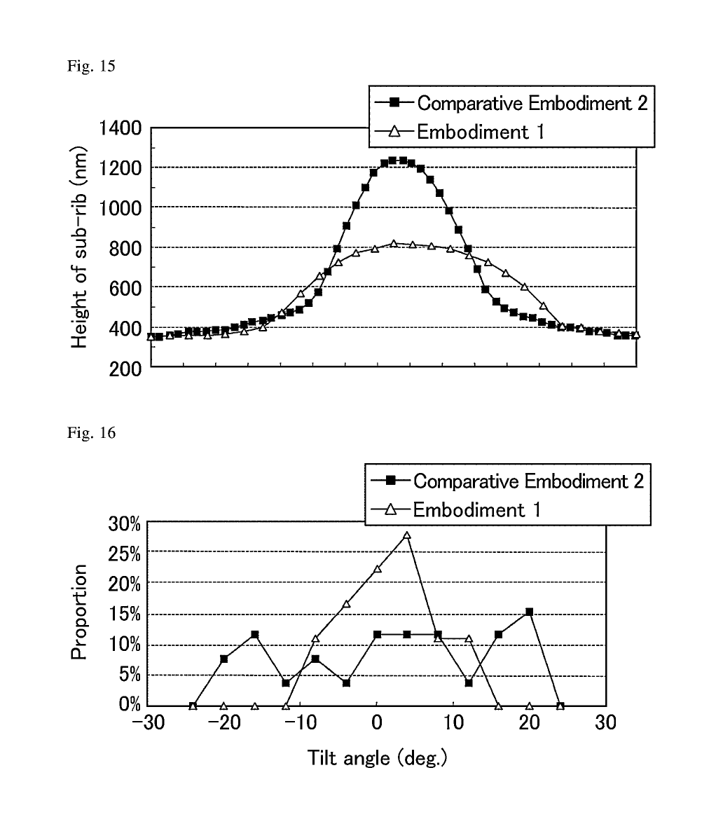

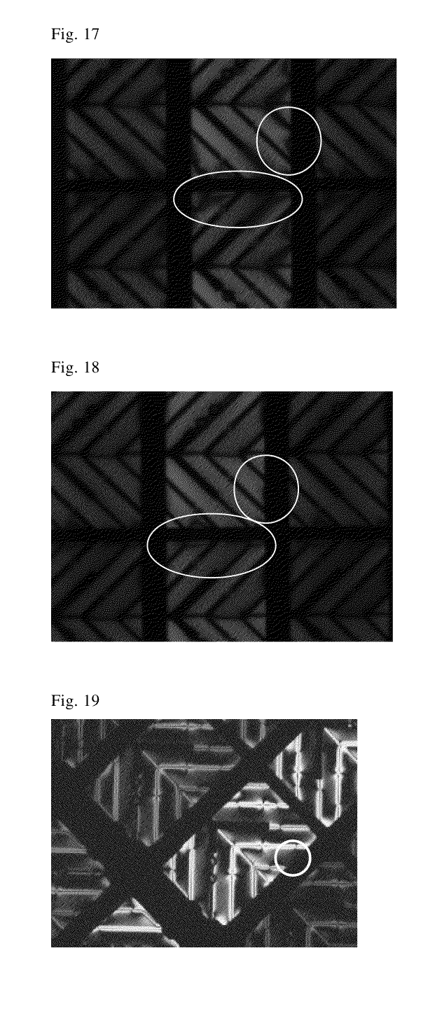

In contrast, the structure of the ribs 21 formed by the production method of Embodiment 1 suppresses such misalignment of the liquid crystal molecules. FIG. 15 shows the result of measuring the profiles of the cross-sectional sectional shapes of the sub-ribs formed by the production methods of Embodiment 1 and Comparative Embodiment 2. The cross-sectional shape herein is a cross-sectional shape in the width direction of a main rib. Further, FIG. 16 shows the distributions of the tilt angles of the surfaces of the sub-ribs formed by the production methods of Embodiment 1 and Comparative Embodiment 2. The data in FIG. 15 and FIG. 16 are obtained using an AFM (atomic force microscope) as a measuring device. The AFM does not set the zero point in the absolute coordinates, and thus the values along the vertical axis in FIG. 15 are relative values. In Comparative Embodiment 2, the sub-ribs are formed using a light-shielding pattern without slits as shown in FIG. 11.

FIG. 15 shows that the sub-ribs 23 in Embodiment 1 are lower and thicker (gentler) than the sub-ribs in Comparative Embodiment 2. Further, FIG. 16 shows that the tilt angles on the surfaces of the sub-ribs 23 gather around smaller angles.

Therefore, the alignment control force of the sub-rib 23 is lower than the alignment control force of the sub-rib in Comparative Embodiment 2. As a result, Embodiment 1 provides a liquid crystal display panel in which the liquid crystal molecules are less likely to be misaligned and which suppresses deterioration in display quality due to misalignment of the liquid crystal molecules.

FIG. 17 is a photomicrograph of the surface of a substrate constituting a liquid crystal display panel of Comparative Embodiment 3 in the normal display state. FIG. 18 and FIG. 19 each are a photomicrograph of the surface of the substrate constituting the liquid crystal display panel of Embodiment 1, where FIG. 18 is a photograph in the normal display state and FIG. 19 is a photograph in the state of an extinction position. In Comparative Embodiment 3, the sub-ribs are formed using a light-shielding pattern without slits as shown in FIG. 11.

The comparison between the white-circled portions in FIG. 17 and the white-circled portions in FIG. 18 shows that the portions in FIG. 17 include dark lines, whereas the portions in FIG. 18 do not include dark lines. As shown in FIG. 19, the circled portion in FIG. 19 does not include a disclination line between the alignment of the liquid crystal molecules owing to the sub-ribs and the alignment of the liquid crystal molecules owing to the main ribs. Therefore, the structure of Embodiment 1 provides better display quality than Comparative Embodiment 3.

As described above, Embodiment 1 enables to pattern the main ribs 22 and the sub-ribs 23 with appropriate shapes simultaneously. Therefore, it enables to easily and efficiently produce a liquid crystal display panel that suppresses misalignment of the liquid crystal molecules.

The GT region 62 has a relatively simple pattern, and thus the photomask 60 can be produced using a lithographic device with a relatively low processing accuracy, such as a lithographic device for large photomasks.

### Embodiment 2

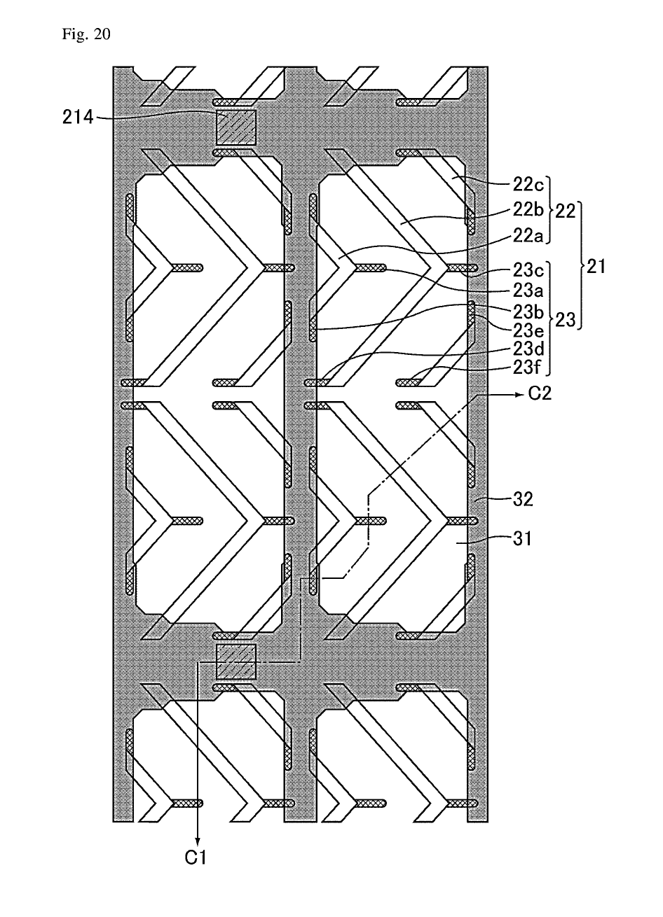

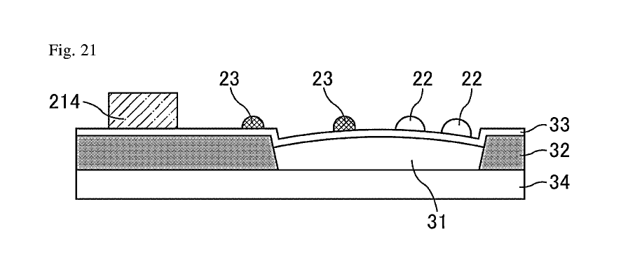

A liquid crystal display panel of Embodiment 2 is the same as the liquid crystal display panel of Embodiment 1 except for the following. As shown in FIG. 20 and FIG. 21, an opposite substrate of Embodiment 2 comprises a spacer 214 instead of the spacer 14. The spacer 214 has no pedestal part 14a and has a monolayer structure.

The following will describe a method for producing the opposite substrate of Embodiment 2. The production method of Embodiment 2 is the same as the production method of Embodiment 1 except for the following.

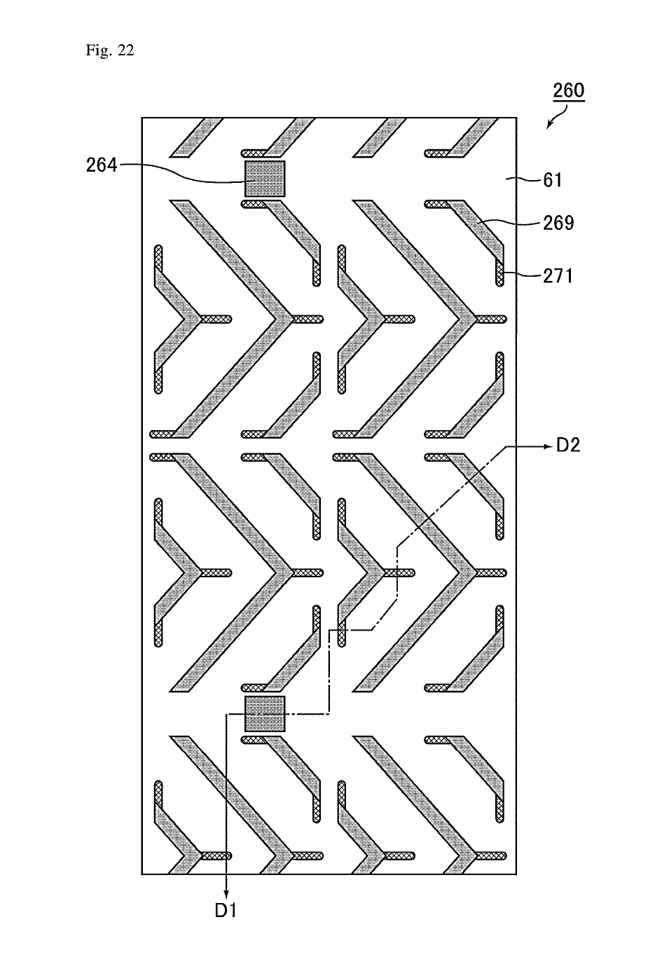

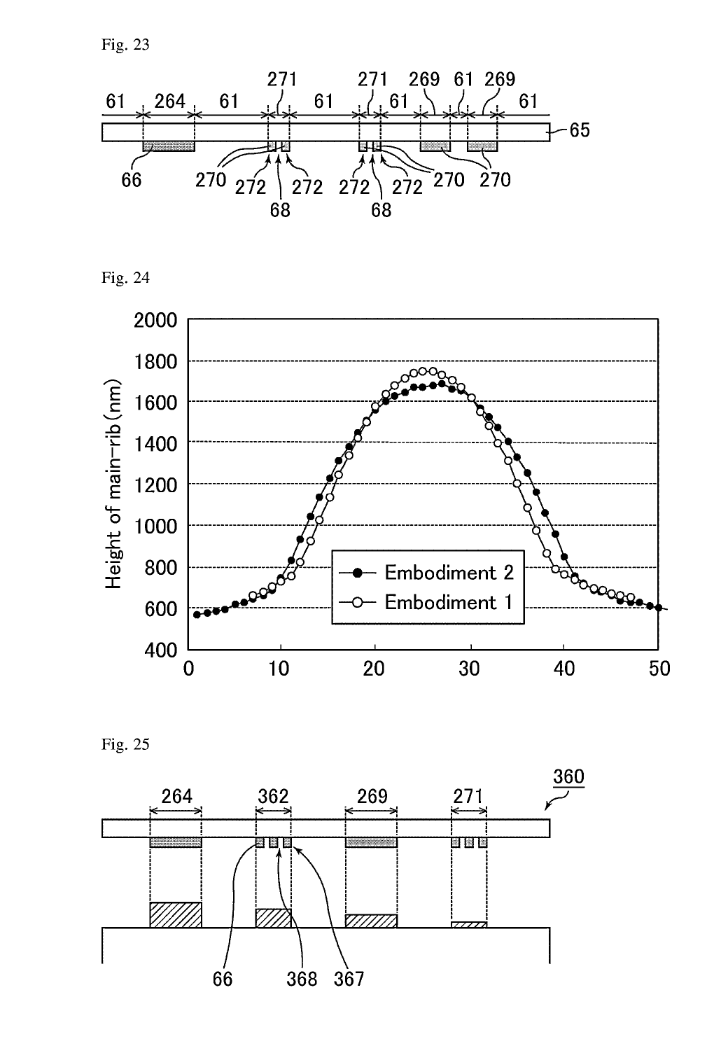

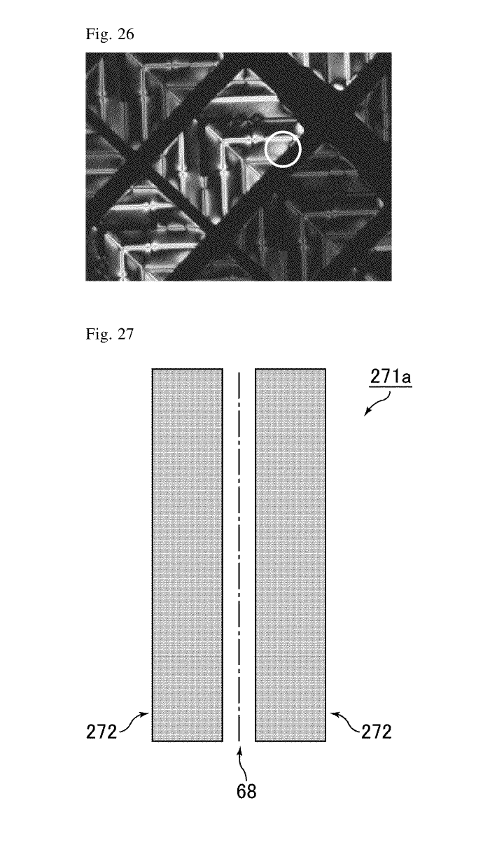

In the present embodiment, a photomask 260 is used instead of the photomask 60. FIG. 22 shows a schematic plan view of the photomask 260 and FIG. 23 shows a schematic cross-sectional view along the D1-D2 line in FIG. 22.

As shown in FIG. 22 and FIG. 23, the photomask 260 has light-shielding regions 264 instead of the light-shielding regions 64. The light-shielding regions 264 are the same as the light-shielding regions 64 except that they correspond to the portions of the resin film 35 that are to be formed into the spacers 214. In other words, the plane pattern of the light-shielding regions 264 is similar to the plane pattern of the spacers 214.

The photomask 260 has half-tone regions (HT regions) 269 instead of the light-shielding regions 63. The HT regions 269 are the same as the light-shielding regions 63 except for the following. In other words, the entire area of each HT region 269 has a partially translucent layer 270 instead of the light-shielding layer 66.

The partially translucent layer 270 is formed by patterning a partially translucent thin film. The partially translucent layer 270 transmits part of light applied. Specifically, the transmissivity of the partially translucent layer 270 at a wavelength of 360 to 440 nm is, for example, 60% or lower, and preferably 25 to 35%. Examples of the material of the partially translucent layer 270 include oxides, nitrides, carbides, oxynitrides, and carbonitrides containing an element(s) such as chromium, molybdenum silicide, tantalum, aluminum, and silicon.

Further, the photomask 260 has half-tone/gray-tone regions (HT/GT regions) 271, which are light-control regions, instead of the GT regions 62. Each of the HT/GT regions 271 has partially translucent parts 272 instead of the light-shielding parts 67. Since the partially translucent parts 272 include partially translucent layers 270, they transmit part of light applied. In other words, the HT/GT regions 271 transmit part of light applied.

The transmissivity of the HT/GT region 271 at a wavelength of 360 to 440 nm is higher than the transmissivity of the GT region 62 at a wavelength of 360 to 440 nm, and it is, for example, 76% or lower, and preferably 45 to 60%. The transmissivity of the HT region 269 is the same as the transmissivity of the partially translucent layer 270. Therefore, the transmissivity in the photomask 260 increases in the order of the light-shielding region 264, the HT region 269, the HT/GT region 271, and the translucent region 61.

Such a photomask 260 enables to remove most parts corresponding to the translucent regions 61 of the resin film 35 and to partially remove the parts corresponding to the HT/GT regions 271 and the HT regions 269 of the resin film 35. Further, it allows most parts corresponding to the light-shielding regions 264 of the resin film 35 to remain. Here, the transmissivity of the HT/GT region 271 is higher than the transmissivity of the HT region 269. This enables to form a lower residual film at a portion corresponding to the HT/GT region 271 and to form a higher residual film at a portion corresponding to the HT region 269.

As a result, the sub-ribs 23 are formed at the portions corresponding to the HT/GT regions 271, the main ribs 22 are formed at the portions corresponding to the HT regions 269, and the spacers 214 are formed at the portions corresponding to the light-shielding regions 64. In other words, the sub-ribs 23, the main ribs 22, and the spacers 214 having different heights are patterned simultaneously.

FIG. 24 shows the result of measuring the profiles of the cross-sectional shapes of the main ribs 22 in Embodiment 1 and Embodiment 2 using an AFM. The cross-sectional shape herein means a cross-sectional shape of the main rib in the width direction. As shown in FIG. 24, a slight difference in profile occurs between the case of using the light-shielding region 63 and the case of using the HT region 269. Such a degree of difference, however, does not affect the display performance and causes no disadvantage.

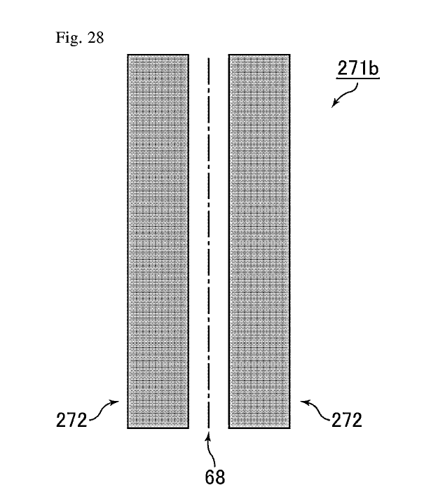

Further, the photomask in the present embodiment preferably has first HT/GT regions 271a and second HT/GT regions 271b shown in FIGS. 27 and 28 similar to the GT regions 62a and the GT regions 62b formed in Embodiment 1. The transmissivity of the HT/GT region 271a is lower than the transmissivity of the HT/GT region 271b. A slit (first translucent part) 68 of the HT/GT region 271a is narrower than a slit (second translucent part) 68 of the HT/GT region 271b. Further, the partially translucent part (first partially translucent part) 272 of the HT/GT region 271a is thicker than the partially translucent part (second partially translucent part) 272 of the HT/GT region 271b. The HT/GT regions 271 a are used for forming the sub-ribs 23a, 23c, 23d, and 23f on the color filter 31, and the HT/GT regions 271b are used for forming the sub-ribs 23b and 23e on the BM 32.

The photomask 260 of the present embodiment can be produced at a relatively low cost. On the other hand, production of a photomask having x half-tone regions with different transmissivities costs as high as production of x photomasks having the same half-tone region. The x is an integer of 2 or greater.

In general, the amount of etching shift of a partially translucent thin film is larger than that of a light-shielding thin film. Thus, it is commonly difficult to accurately process a partially translucent thin film. However, the HT/GT region 271 has a relatively simple pattern in the present embodiment. Therefore, the present embodiment enables to accurately produce the photomask 260 having the HT/GT region 271.

### Embodiment 3

Embodiment 3 is the same as Embodiment 2 except for the following.

In the present embodiment, a photomask 360 is used instead of the photomask 260. FIG. 25 shows a schematic cross-sectional view of the photomask 360. FIG. 25 shows that the photomask 360 has a GT region 362 in addition to the light-shielding region 264, the HT region 269, and the HT/GT region 271.

The GT region 362 is formed on the basis of the same spirit of the GT region 62 of Embodiment 1. In other words, the GT region 362 has light-shielding parts 367 including light-shielding layers 66 and a slit-like (linear) translucent part (slit) 368. The slit 368 and the light-shielding parts 367 form a stripe pattern. The slit 368 extends in a direction corresponding to the extending direction of the pattern formed by the GT region 362. The slit 368 is substantially uniform in width, and the width of the slit 368 is narrower than the resolution limit of the exposure device.

The number of slits 368 in one GT region 362 is not particularly limited. For two or more slits 368, the respective slits 368 have substantially the same width.

For a single slit 368, the center line of the slit 368 is substantially identical to the center line of the GT region 362. Further, for two or more slits 368, the slits 368 are disposed at uniform intervals. In either case, the light-shielding parts 367 each are substantially uniform in width and the light-shielding parts 367 have substantially the same width.

The transmissivities of the HT region 269, the HT/GT region 271, and the GT region 362 are easily adjustable. For example, the transmissivities of the HT region 269 and the HT/GT region 271 are adjustable by modifying the transmissivity of the partially translucent layer 270. Further, the transmissivities of the HT/GT region 271 and the GT region 362 are adjustable by modifying the number and/or the width of the slits. This enables to differentiate the transmissivities of the light-shielding region 264, the HT region 269, HT/GT region 271, and the GT region 362. As a result, the heights of the residual films corresponding to the light-shielding region 264, the HT region 269, the HT/GT region 271, and the GT region 362 are made different from each other. In other words, the present embodiment provides four patterns with different heights.

As shown in FIG. 25, for example, the heights of the residual films corresponding to the light-shielding region 264, the GT region 362, the HT region 269, and the HT/GT region 271 decrease in the order set forth.

The four patterns with different heights may include a sub-columnar spacer and a protection pattern, for example, in addition to the columnar spacer 214, the main rib 22, and the sub-rib 23.

The sub-columnar spacer is lower than the spacer 214, and the difference in height between them is about 1 μm. Preferably, the sub-columnar spacer is lower than the spacer 214 by about 0.6 to 1.5 μm. The spacer 214 adjusts the cell gap, but the spacer 214 may possibly be broken by an external pressure on the panel. Thus, the sub-columnar spacer is disposed as an auxiliary spacer functioning when an external pressure at a certain pressure or higher is applied.

For a common liquid crystal display panel, the array substrate and the opposite substrate face to each other at an interval as narrow as 2 to 5 μm. Thus, an external pressure applied to the panel may make the two lines on the array substrate be in contact with the common electrode of the opposite substrate, causing leak or break of elements. In order to prevent such disadvantage, a protection pattern that is an insulator is disposed as a passivation film. The plane shape of the protection pattern is not specifically limited, and examples thereof include a stripe shape, a dot shape, and a continuous shape. Further, the protection pattern faces the lines on the array substrate based on the above viewpoint. The height of the protection pattern has no clear standards, and it is adjusted to a height that ensures insulation and does not obstruct the function as a structure. As long as these adjustment conditions are satisfied, the height of the protection pattern is preferably as low as possible.

The present application claims priority to Patent Application No. 2010-225964 filed in Japan on Oct. 5, 2010 under the Paris Convention and provisions of national law in a designated State, the entire contents of which are hereby incorporated by reference.

### REFERENCE SIGNS LIST

14, 214: columnar spacer

14a: pedestal part

14b: height-adjusting part

21: rib (liquid crystal alignment control projection)

22, 22a to 22c: main rib (main projection)

23, 23a to 23f: sub-rib (sub-projection)

31: color filter (color layer)

32: black matrix (BM, light-shielding layer)

33: common electrode

34: substrate

35: photosensitive resin film

60, 260, 360: photomask

61: translucent region

62, 62a, 62b, 362: gray-tone region (GT region, light-control region)

63, 64, 264: light-shielding region

65: substrate (support)

66: light-shielding layer

67, 367: light-shielding part

68, 368: translucent part (slit)

269: half-tone region (HT region, light-control region)

270: partially translucent layer

271: half-tone/gray-tone region (HT/GT region, light-control region)

272: partially translucent part

S: main control domain

W: sub control domain

1. A method for producing a substrate for a liquid crystal display panel, the substrate comprising liquid crystal alignment control projections including a main projection and a sub-projection that is linear and is lower than the main projection,
the method comprising:
a step of forming a positive photosensitive resin film; and
a step of exposing the photosensitive resin film to light through a photomask,
the photomask including a light-control region for forming the sub-projection, and
the light-control region including a slit-shaped translucent part.

2. The method for producing a substrate for a liquid crystal display panel according to claim 1,
wherein the photomask further includes a translucent region and a light-shielding region for forming the main projection, and
the light-control region is a gray-tone region including a light-shielding part and the translucent part.

3. The method for producing a substrate for a liquid crystal display panel according to claim 2,
wherein the substrate further comprises a color layer and a light-shielding layer that is higher than the color layer;
the sub-projection is a first sub-projection disposed on the color layer;
the liquid crystal alignment control projections further include a second sub-projection disposed on the light-shielding layer; and
the second sub-projection is linear and is lower than the main projection, and
wherein the gray-tone region is a first gray-tone region for forming the first sub-projection;
the light-shielding part and the translucent part are a first light-shielding part and a first translucent part, respectively;
the photomask further includes a second gray-tone region for forming the second sub-projection;
the second gray-tone region includes a second light-shielding part and a slit-shaped second translucent part; and
the second gray-tone region has a higher transmissivity than the first gray-tone region.

4. The method for producing a substrate for a liquid crystal display panel according to claim 1,
wherein the substrate further comprises a columnar spacer, and
wherein the photomask further includes a translucent region, a light-shielding region for forming the columnar spacer, and a half-tone region for forming the main projection; and
the light-control region is a half-tone/gray-tone region including a partially translucent part and the translucent part.

5. The method for producing a substrate for a liquid crystal display panel according to claim 4,
wherein the substrate further comprises a color layer and a light-shielding layer that is higher than the color layer;
the sub-projection is a first sub-projection that is disposed on the color layer;
the liquid crystal alignment control projections further include a second sub-projection disposed on the light-shielding layer; and
the second sub-projection is linear and is lower than the main projection, and
wherein the half-tone/gray-tone region is a first half-tone/gray-tone region for forming the first sub-projection;
the partially translucent part and the translucent part are a first partially translucent part and a first translucent part, respectively;
the photomask further includes a second half-tone/gray-tone region for forming the second sub-projection;
the second half-tone/gray-tone region includes a second partially translucent part and a slit-shaped second translucent part; and
the second half-tone/gray-tone region has a higher transmissivity than the first half-tone/gray-tone region.

6. The method for producing a substrate for a liquid crystal display panel according to claim 4,
wherein the translucent part is a first translucent part;
the photomask further includes a gray-tone region; and
the gray-tone region includes a light-shielding part and a slit-shaped second translucent part.

7. A photomask which is used in a process of producing a substrate for a liquid crystal display panel, the substrate comprising liquid crystal alignment control projections including a main projection and a sub-projection that is linear and is lower than the main projection,
the photomask comprising:
a light-control region for forming the sub-projection, and
the light-control region including a slit-shaped translucent part.
